(19) United States
(12) Patent Application Publication
(10) Pub. No.: US 2008/0291639 A1
(43) Pub. Date: Nov. 27, 2008

(54) COMMUNICATION MODULE PACKAGE ASSEMBLY

(75) Inventors: Kuan-Hsing Li, Taichung City (TW); Kuo-Hsien Liao, Taichung City (TW); Jia-Yang Chen, Taichung City (TW)

Correspondence Address: BROWDY AND NEIMARK, P.L.L.C.;624 NINTH STREET, NW, SUITE 300, WASHINGTON, DC, 20001-5303, US

(73) Assignee: Universal Scientific Industrial Co., Ltd., Tsao Tuen (TW)

(21) Appl. No.: 11/943,236

(22) Filed: Nov. 20, 2007

(30) Foreign Application Priority Data
May 22, 2007 (TW) 96208176

(51) Int. Cl. H05K 7/20

(52) U.S. Cl. 361/719

(57) ABSTRACT

A communication module package assembly includes a main board having grounding pads, a communication module package electrically bonded on the main board and having notches corresponding in location to the grounding pads respectively, and a metal cover covering the communication module package and having mounting legs passing through the notches and electrically connected to the grounding pads respectively. The communication module package is of stacked structure including a carrier with an opening in which a thermal conductive layer in contact with a substrate stacked on the carrier is filled. The communication module package further includes a chip electrically bonded to the substrate, received in the opening and encapsulated by the thermal conductive layer, and a metal layer sandwiched between and in contact with the thermal conductive layer and the main board.

### BACKGROUND OF THE INVENTION

1. Field of the Invention

The present invention relates generally to a communication module and more particularly, to a communication module package assembly including a communication module package of stacked structure bonded on a main board and capped with a metal cap.

2. Description of the Related Art

A communication module is designed for use in an electronic apparatus to provide a wireless communication function. Following market demands, electronic products, such as cell phones, PDAs and etc., are made having compact and multi-function characteristics. Therefore, modern electronic produces are commonly small-sized. To reduce the size, a conventional communication module package adopts stacked package technology. By means of stacking circuit module(s) on a carrier, a communication module package of stacked structure can be made having compact and multi-function characteristics.

However, when reducing the size of a wireless communication module package, the heat dissipation requirement must be more critical. Conventional package structures for communication module commonly dissipate heat by air. However, the thermal conductivity of air is only about 0.025 W/m·K at room temperature. Because a wireless communication module package is substantially an enclosed structure, it is not in favor of air convection, and beat energy tends to be accumulated inside the package. As a result, conventional communication module packages cannot dissipate heat rapidly, i.e., conventional communication module packages commonly have the drawback of low heat dissipation efficiency. Further, in a conventional communication module package, connections between elements are achieved by means of solder pads only. This connection structure has a weak structural strength. An impact or falling of the stack package structure may cause concentration of stress and severe damage.

Further, a conventional communication module package is generally equipped with a metal cover, which is grounded by means of grounding pads or grounding via holes to isolate electromagnetic interference. However, this grounding design cannot eliminate parasitic capacitance or resistance, i.e., it cannot effectively eliminate electromagnetic interference.

Therefore it is desirable to provide a communication module package assembly that eliminates the aforesaid problems.

### SUMMARY OF THE INVENTION

The present invention has been accomplished under the circumstances in view. It is the primary objective of the present invention to provide a communication module package assembly, which can provide a good heat dissipation effect and good structural strength.

It is another objective of the present invention to provide a communication module package assembly, which can provide a good grounding effect to minimize the electromagnetic interference.

To achieve the above-mentioned objectives, a communication module package assembly provided by the present invention comprises a main board having grounding pads, a communication module package electrically bonded on the main board and having notches corresponding in location to the grounding pads respectively, and a metal cover covering the communication module package and having mounting legs passing through the notches and electrically connected to the grounding pads respectively. The communication module package is of stacked structure comprising a carrier with an opening in which a thermal conductive layer in contact with a substrate stacked on the carrier is filled. The communication module package may further include a chip electrically bonded to the substrate, received in the opening and encapsulated by the thermal conductive layer, and a metal layer sandwiched between and in contact with the thermal conductive layer and the main board.

In a first exemplary embodiment of the present invention to be detailedly described hereinafter, the communication module package comprises a carrier and a substrate stacked on the carrier. The carrier has a top bearing surface, a bottom bearing surface electrically bonded to the main board, an opening through the top bearing surface and the bottom bearing surface, and a plurality of notches corresponding to the grounding pads of the main board respectively. The substrate has a top surface on which a plurality of grounding pads are provided, a bottom surface electrically bonded to the top bearing surface of the carrier, and a plurality of notches aligned with the notches of the carrier respectively so as to define with the notches of the carrier the notches of the communication module package. In addition, the metal cover has a plurality of first mounting legs respectively and electrically connected to the grounding pads at the top surface of the substrate, and a plurality of second mounting legs respectively passing through the aligned notches of the substrate and the carrier and electrically connected to the grounding pads of the main board.

In a second exemplary embodiment of the present invention to be detailedly described hereinafter, the communication module package comprises a first carrier, a first substrate, a second carrier and a second substrate stacked one another. The first carrier has an opening in which a first thermal conductive layer is filled and in contact with the first substrate. The second carrier has an opening in which a second thermal conductive layer is filled and in contact with the second substrate. The communication module package further comprises at least a first chip electrically mounted on the bottom surface of the first substrate, received in the opening of the first carrier and encapsulated by the first thermal conductive, and at least a second chip electrically mounted on the bottom surface of the second substrate, received in the opening of the second carrier and encapsulated by the second thermal conductive layer.

The communication module package assembly of the present invention uses an electrically insulative and thermally conductive material for packaging, improving the heat dissipation effect of the communication module and overcoming the drawback of poor heat dissipation effect of the prior art design. Further, the communication module package assembly can disperse external impact by means of the thermal conductive layer, eliminating concentration of stress and preventing damage to electrically connecting portions of the pads. Therefore, the invention is not only applicable to the fabrication of a communication module package of stacked structure having more than three layers but also can provide a good structural strength. Further, the metal cover is directly grounded with the main board to prevent parasitic capacitance and resistance, improving the grounding effect and reducing electromagnetic interference.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given herein below and the accompanying drawings which are given by way of illustration only, and thus are not limitative of the present invention, and wherein:

FIG. 1 is a schematic drawing showing a substrate and a carrier of a communication module package in accordance with a first preferred embodiment of the present invention;

FIG. 2 is another schematic drawing showing the substrate and the carrier are bonded together;

FIG. 3 is still another drawing showing that a thermal conductive layer is filled with the opening of the carrier and covers the chips;

FIG. 4 is still another schematic drawing showing that a metal layer is disposed on the thermal conductive layer;

FIG. 5 is an exploded schematic drawing showing a metal cover and the combined substrate and carrier;

FIG. 6 is a schematic drawing showing installation of the main board;

FIG. 7 is a schematic perspective view of the communication module package assembly in accordance with the first embodiment of the present invention;

FIG. 8 is a sectional view taken along line 8-8 of FIG. 7; and

FIG. 9 is a schematic sectional view of a communication module package assembly in accordance with a second embodiment of the present invention.

### DETAILED DESCRIPTION OF THE INVENTION

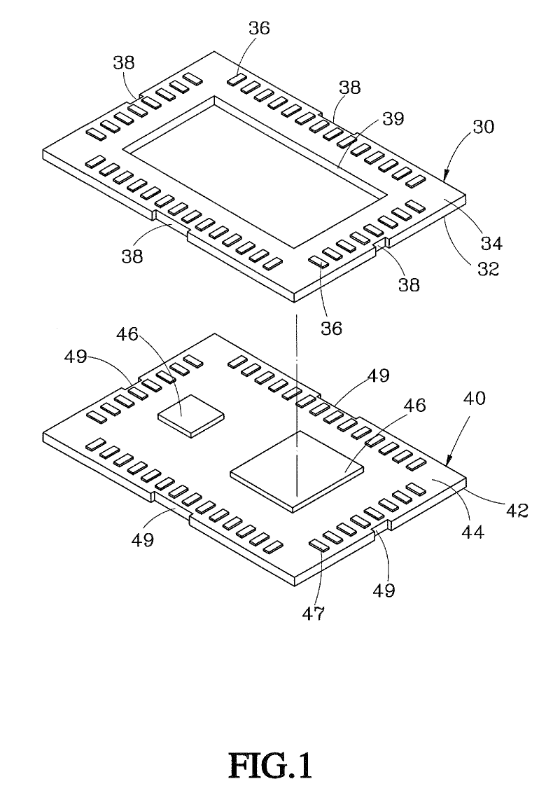

Referring to FIGS. 1-8, a communication module package assembly 10 in accordance with a preferred embodiment of the present invention is shown comprising a main board 20, a communication module package of stacked structure including a carrier 30, a substrate 40, a thermal conductive layer 50 and a metal layer 60, and a metal cover 70.

The main board 20 has arranged on its top surface a plurality of contact pads 22 and grounding pads 24.

The carrier 30 of the communication module package is bonded to the top surface of the main board 20 and electrically connected to the main board 20. The carrier has a top bearing surface 32, a bottom bearing surface 34, a plurality of contact pads 36, and a plurality of notches 38. The contact pads 36 are arranged on the top bearing surface 32 and the bottom bearing surface 34. In addition, the contact pads at the top bearing surface 32 are electrically connected to the contact pads at the bottom bearing surface 34. The contact pads 36 at the bottom bearing surface 34 are electrically connected to the contact pads 22 of the main board 20. The carrier 30 farther has an opening 39 through the top bearing surface 32 and the bottom bearing surface 34. The notches 38 are formed on the periphery of the carrier 30 corresponding in location to the grounding pads 24 of the main board 20.

The substrate 40 of the communication module package has a top surface 42, a bottom surface 44, a plurality of contact pads 47, a plurality of grounding pads 48, and a plurality of notches 49 formed on the periphery thereof. The contact pads 47 are respectively arranged on the top surface 42 and the bottom surface 44. The contact pads 47 at the bottom surface 44 of the substrate 40 are electrically connected to the contact pads 36 at the top bearing surface 32 of the carrier 30 in such a way that the notches 49 formed on the periphery of the substrate 40 are aligned with the notches 38 of the carrier 30 and aimed at the grounding pads 24 of the main board 20. In this preferred embodiment, the communication module package further comprises three chips 46, two of which are electrically mounted on the bottom surface 44 of the substrate 40 and received in the opening 39 of the carrier 30, and one of which is electrically mounted on the top surface 42 of the substrate 40. It is to be easily understood that the communication module package can be designed containing one or more chips of various functions, which can be mounted on the top surface 42 and/or the bottom surface 44 of the substrate 40, depending on the requirement of the communication module package.

The thermal conductive layer 50 of the communication module package is formed of an electrically insulative and thermally conductive material and filled up the opening 39 of the carrier 30. The thermal conductivity layer 50 is bonded to the bottom surface 44 of the substrate 40 and encapsulates the IC chips 46 at the bottom surface 44 of the substrate 40. The thermal conductive layer 50 has a thermal conductivity greater than 0.2 W/m·K. The thermal conductive layer 50 can be prepared from epoxy resin, silicon resin, silicon-filled epoxy resin, or polyester resin. Preferably, the thermal conductive layer 50 is prepared from epoxy resin that has a thermal conductivity about 0.63 W/m K.

The metal layer 60 is covered on the free surface of the thermal conductive layer 50 and closely attached to the main board 20 to enhance the heat dissipation effect of the thermal conductive layer 50.

The metal cover 70 is capped on the communication module package and covers the top surface 42 of the substrate 40. The metal cover 70 has a plurality of first mounting legs 72 and a plurality of second mounting legs 74. The first mounting legs 72 have a length smaller than the length of the second mounting legs 74. The first mounting legs 72 are respectively electrically connected to the grounding pads 48 at the top surface 42 of the substrate 40, and the second mounting legs 74 are respectively inserted through the notches 49 of the substrate 40 and the notches 38 of the carrier 30 and then electrically connected to the grounding pads 24 of the main board 20. The notches 38 of the carrier 30 have a width slightly greater than the width of the notches 49 of the substrate 40 for enabling solder wicking when electrically connecting the second mounting legs 74 of the metal cover 70 to the grounding pads 24 of the main board 20.

The method of making the communication module package assembly 10 according to the first preferred embodiment of the present invention is outlined hereinafter with reference to FIGS. 1-8.

1. At first, Apply solder paste on the contact pads 47 at the bottom surface 44 of the substrate 40 and the contact pads 36 at the top bearing surface 32 of the carrier 30, as shown in FIG. 1.

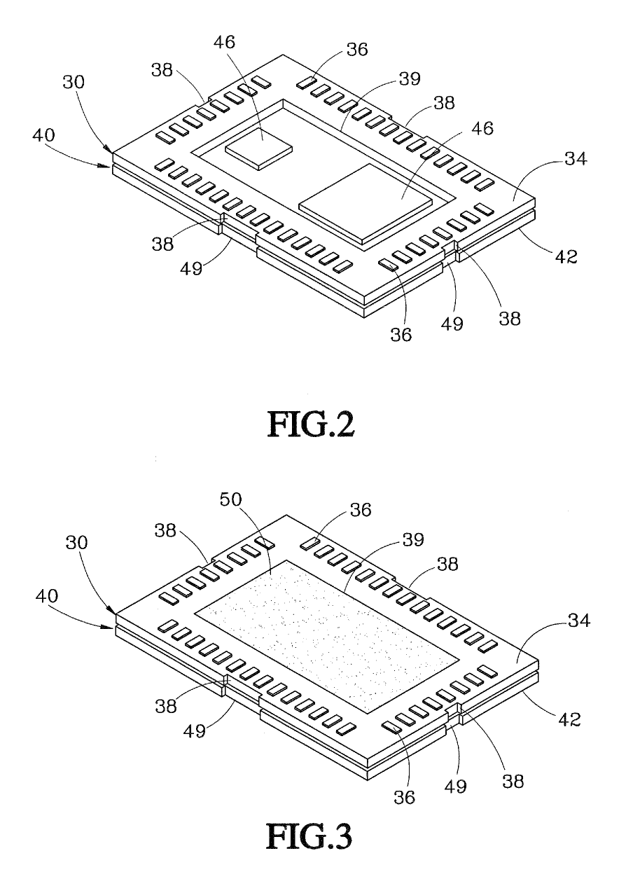

2. Place the carrier 30 on the bottom side of the substrate 40 to attach the contact pads 36 at the top bearing surface 32 of the carrier 30 to the contact pads 47 at the bottom surface 44 of the substrate 40 and to have the IC chips 46 of the substrate 40 be suspended in the opening 39 of the carrier 30, and then heating the applied solder paste to have the carrier 30 and the substrate 40 be bonded together by the solder paste, such that the carrier 30 and the substrate 40 are bonded together as shown FIG. 2.

3. Fill up the opening 39 of the carrier 30 with an electrically insulative and thermally conductive material to form the desired thermal conductive layer 50 that is bonded to the bottom surface 44 of the substrate 40 and that encapsulates the IC chips 46 at the bottom surface 44 of the substrate 40, as shown in FIG. 3.

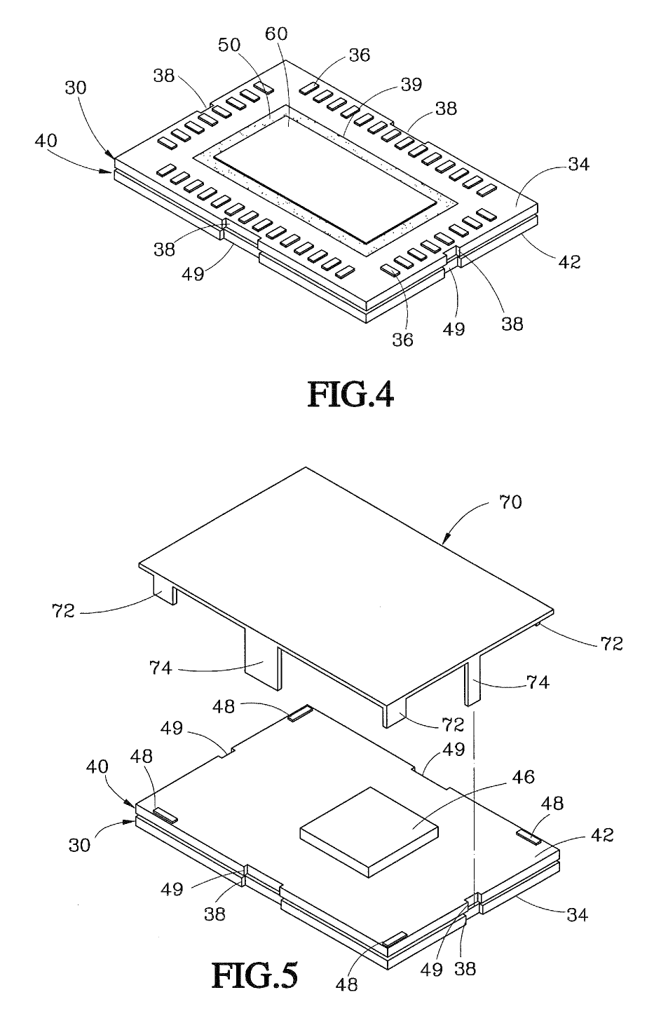

4. Coat the free surface of the thermal conductive layer 50 with a layer of metal material to form the desired metal layer 60, as shown in FIG. 4, to form a communication module package.

5. Apply solder paste on the grounding pads 48 at the top surface 42 of the substrate 40, and then aim the first mounting legs 72 of the metal cover 70 at the grounding pads 48 at the top surface 42 of the substrate 40, and then heat the solder paste to have the substrate 40 and the metal cover 70 be bonded together by the solder paste as shown in FIG. 5.

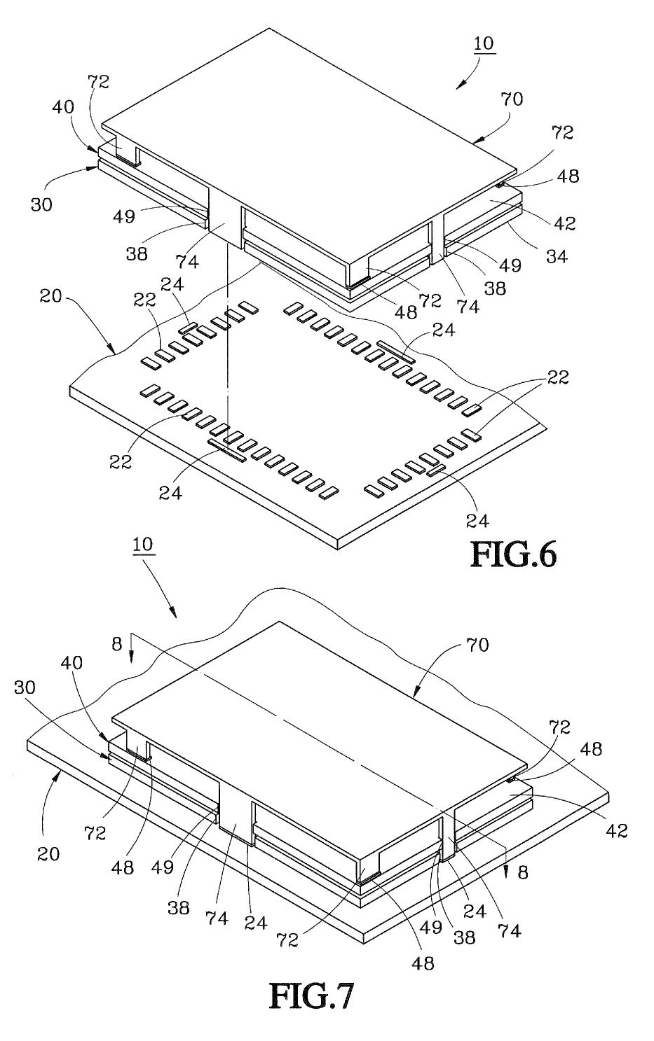

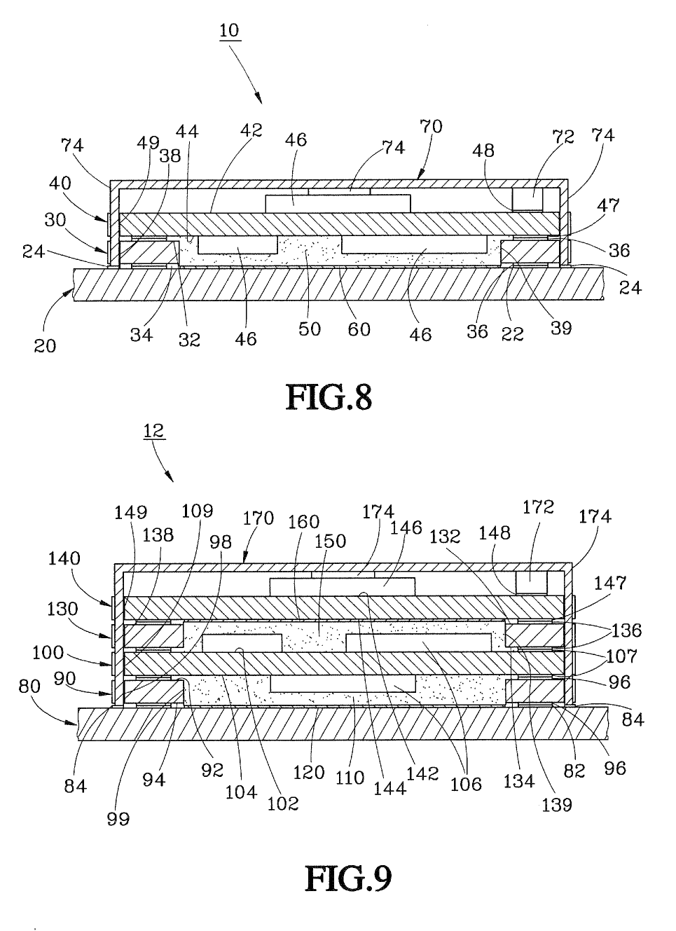

6. Apply solder paste on the contact pads 36 at the bottom bearing surface 34 of the carrier 30 and the contact pads 22 and grounding pads 24 of the main board 20, and then keep the contact pads 36 at the bottom bearing surface 34 of the carrier 30 in alignment with the contact pads 22 of the main board 20 and the second mounting legs 74 of the metal cover 70 in alignment with the grounding pads 24 of the main board 20, and then heat the applied solder paste to have the main board 20, the carrier 30 and the metal cover 70 be bonded together by the solder paste as shown in FIG. 6. Thus, obtain the communication module package assembly 10 as shown in FIGS. 7 and 8.

According to the aforesaid first preferred embodiment of the present invention, the communication module package assembly 10 uses an electrically insulative and thermally conductive material for packaging, improving the heat dissipation efficiency of the communication module and overcoming the drawback of poor heat dissipation effect of the prior art design. Further, the communication module package assembly 10 can disperse external impact by means of the thermal conductive layer 50, eliminating concentration of stress and preventing damage to electrically connecting portions of the pads 22, 36, 47. Therefore, the invention is applicable to the fabrication of a communication module package of stacked structure having more than three layers, that is, the present invention has a good structural strength. Further, the metal cover 70 is directly grounded with the main board 20 to prevent parasitic capacitance and resistance, improving the grounding effect and reducing electromagnetic interference.

FIG. 9 illustrates a communication module package assembly 12 in accordance with a second preferred embodiment of the present invention. The communication module package assembly 12 comprises a main board 80, a communication module package including a first carrier 90, a first substrate 100, a first thermal conductive layer 110, a first metal layer 120, a second carrier 130, a second substrate 140, a second thermal conductive layer 150 and a second metal layer 160, and a metal cover 170.

The main board 80 has arranged on its top surface a plurality of contact pads 82 and a plurality of grounding pads 84.

The first carrier 90 has a top bearing surface 92, a bottom bearing surface 94, a plurality of contact pads 96 located on the top and bottom bearing surfaces 92 and 94 respectively, and a plurality of notches 98 formed around the periphery thereof. In addition, the contact pads at the top bearing surface 92 are electrically connected to the contact pads at the bottom bearing surface 94. The contact pads 96 at the bottom bearing surface 94 are electrically connected to the contact pads 82 of the main board 80, such that the notches 98 correspond in location to the grounding pads 84 of the main board 80. The first carrier 90 further has an opening 99 cut through the top bearing surface 92 and the bottom bearing surface 94.

The first substrate 100 has a top surface 102, a bottom surface 104, a plurality of contact pads 107 located on the top and bottom surfaces 102 and 104 respectively, and a plurality of notches 109 formed around the periphery thereof. In this embodiment, two IC chips 106 are electrically mounted on the top surface 102 of the substrate 100, and an IC chip 106 is electrically mounted on the bottom surface 104 of the first substrate 100 and received in the opening 99 of the first carrier 90. The contact pads 107 at the bottom surface 104 of the first substrate 100 are electrically connected to the contact pads 96 at the top bearing surface 92 of the first carrier 90, such that the notches 109 of the first substrate 100 are aligned with the notches 98 of the first carrier 90 and correspond in location to the grounding pads 84 of the main board 80.

The first thermal conductive layer 110 is formed of an electrically insulative and thermally conductive material and filled up the opening 99 of the first carrier 90. The thermal conductivity layer 110 is bonded to the bottom surface 104 of the first substrate 100 and encapsulates the IC chip 106 at the bottom surface 104 of the first substrate 100.

The first metal layer 120 is sandwiched between and in contact with the first thermal conductive layer 110 and the main board 80 to enhance the heat dissipation effect of the first thermal conductive layer 110.

The second carrier 130 has a top bearing surface 132, a bottom bearing surface 134, a plurality of contact pads 136 on the top bearing surface 132 and the bottom bearing surface 134, and a plurality of notches 138 around the periphery thereof. In addition, the contact pads at the top bearing surface 132 are electrically connected to the contact pads at the bottom bearing surface 134. The contact pads 136 located at the bottom bearing surface 134 are electrically connected to the contact pads 107 at the top surface 102 of the first substrate 100. The second carrier 130 further has an opening 139 cut through the top bearing surface 132 and the bottom bearing surface 134 for accommodating the IC chips 106 at the top surface 102 of the first substrate 100. The notches 138 are respectively in alignment with the notches 109 of the first substrate 100 such that they correspond in location to the grounding pads 84 of the main board 80 respectively.

The second substrate 140 has a top surface 142, a bottom surface 144, a plurality of contact pads 147 on the bottom surface 144, a plurality of grounding pads 148 on the top surface 142, and a plurality of notches 149 around the periphery thereof. In this embodiment, an IC chip 146 is electrically mounted on the top surface 142 of the second substrate 140. The contact pads 147 of the second substrate 140 are electrically connected to the contact pads 136 at the top bearing surface 132 of the second carrier 130. The notches 149 are in alignment with the notches 138 of the second carrier 130, so that they correspond in location to the grounding pads 84 of the main board 80.

The second thermal conductive layer 150 is formed of an electrically insulative and thermally conductive material and filled up the opening 139 of the second carrier 130, so that the second thermal conductive layer 150 encapsulates the IC chips 160 located at the top surface 102 of the first substrate 100.

The second metal layer 160 is sandwiched between and in contact with the second thermal conductive layer 150 and the bottom surface 144 of the second substrate 140 to enhance the heat dissipation effect of the second thermal conductive layer 150.

The metal cover 170 is capped on the communication module package and covers the top surface 142 of the second substrate 140. The metal cover 170 has a plurality of first mounting legs 172 and a plurality of second mounting legs 174 around the border. The first mounting legs 172 have a length smaller than the length of the second mounting legs 174. The first mounting legs 172 are respectively electrically connected to the grounding pads 148 at the top surface 142 of the second substrate 140, the second mounting legs 174 are respectively inserted through the notches 109 and 149 of the first substrate 100 and second substrate 140 and the notches 90 and 138 of the first carrier 90 and second carrier 130 and then electrically connected to the grounding pads 84 of the main board 80. The notches 98 of the first carrier 90 have a width slightly greater than the width of the notches 109, 138 and 149 of the first substrate 100, second carrier 130 and second substrate 140 for solder wicking when electrically connecting the second mounting legs 174 of the metal cover 170 to the grounding pads 84 of the main board 80.

According to the aforesaid second preferred embodiment, the communication module package assembly 12 uses an electrically insulative and thermally conductive material for packaging, improving the heat dissipation efficiency of the communication module and overcoming the drawback of poor heat dissipation effect of the prior art design. Further, the communication module package assembly 12 can disperse external impact by means of the thermal conductive layers 110 and 150, eliminating concentration of stress and preventing damage to electrically connecting portions of the contact pads. Therefore, the invention is applicable to the fabrication of a communication module package of stacked structure having more than three layers, that is, the present invention has a good structural strength. Further, the metal cover is directly grounded with the main board to prevent parasitic capacitance and resistance, improving the grounding effect and reducing electromagnetic interference.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

What is claimed is:

1. A communication module package assembly comprising:
a main board having a top surface on which a plurality of grounding pads are provided;
a communication module package including:
a carrier having a top bearing surface, a bottom bearing surface electrically bonded to the main board, an opening through the top bearing surface and the bottom bearing surface, and a plurality of notches corresponding to the grounding pads of the main board respectively;
a substrate having a top surface on which a plurality of grounding pads are provided, a bottom surface electrically bonded to the top bearing surface of the carrier, and a plurality of notches aligned with the notches of the carrier respectively; and
a thermal conductive layer formed of an electrically insulative and thermally conductive material and filled up the opening of the carrier; and
a metal cover covering the communication module package and having a plurality of first mounting legs respectively and electrically connected to the grounding pads at the top surface of the substrate, and a plurality of second mounting legs respectively passing through the aligned notches of the substrate and the carrier and electrically connected to the grounding pads of the main board.

2. The communication module package assembly of claim 1, wherein the thermal conductive layer has a thermal conductivity greater than 0.2 W/m·K.

3. The communication module package assembly of claim 1, wherein the thermal conductive layer is made by a material selected from the group consisting of epoxy resin, silicon resin, silicon-filled epoxy resin and polyester resin.

4. The communication module package assembly of claim 1, wherein the thermal conductive layer is in contact with the bottom surface of the substrate.

5. The communication module package assembly of claim 1, wherein the communication module package further comprises a metal layer sandwiched between and in contact with the thermal conductive layer and the main board.

6. The communication module package assembly of claim 1, wherein the first mounting legs of the metal cover have a length smaller than the length of the second mounting legs.

7. The communication module package assembly of claim 1, wherein the notches of the carrier have a width greater than the width of the notches of the substrate.

8. The communication module package assembly of claim 1, wherein the substrate, the carrier and the main board each have a plurality of contact pads for electrical connection.

9. The communication module package assembly of claim 1, wherein the communication module package comprises a chip electrically mounted on the bottom surface of the substrate, received in the opening of the carrier and encapsulated by the thermal conductive layer.

10. A communication module package assembly comprising:
a main board having a top surface on which a plurality of grounding pads are provided;
a communication module package including:
a first carrier having a top bearing surface, a bottom bearing surface electrically bonded to the main board, an opening through the top bearing surface and the bottom bearing surface, and a plurality of notches corresponding to the grounding pads of the main board respectively;
a first substrate having a top surface, a bottom surface electrically bonded to the top bearing surface of the first carrier, and a plurality of notches aligned with the notches of the first carrier respectively;
a first thermal conductive layer formed of an electrically insulative and thermally conductive material and filled up the opening of the first carrier;
a second carrier having a top bearing surface, a bottom bearing surface electrically bonded to the top surface of the first substrate, an opening through the top and bottom bearing surfaces thereof, and a plurality of notches aligned with the notches of the first substrate respectively;
a second substrate having a top surface on which a plurality of grounding pads are provided, a bottom surface electrically bonded to the top bearing surface of the second carrier, and a plurality of notches aligned with the notches of the second carrier respectively; and
a second thermal conductive layer formed of an electrically insulative and thermally conductive material and filled up the opening of the second carrier; and
a metal cover covering the communication module package and having a plurality of first mounting legs respectively and electrically connected to the grounding pads at the top surface of the second substrate, and a plurality of second mounting legs respectively passing through the aligned notches of the second substrate, the second carrier, the first substrate and the first carrier and electrically connected to the grounding pads of the main board.

11. The communication module package assembly of claim 10, wherein the first and second thermal conductive layers each have a thermal conductivity over 0.2 W/m·K.

12. The communication module package assembly of claim 10, wherein the first and second thermal conductive layers each are made by a material selected from the group consisting of epoxy resin, silicon resin, silicon-filled epoxy resin and polyester resin.

13. The communication module package assembly of claim 10, wherein the first thermal conductive layer is in contact with the bottom surface of the first substrate.

14. The communication module package assembly of claim 10, wherein the second thermal conductive layer is in contact with the top surface of the first substrate.

15. The communication module package assembly of claim 10, wherein the communication module package further comprises a first metal layer sandwiched between and in contact with the first thermal conductive layer and the main board, and a second metal layer sandwiched between and in contact with the second thermal conductive layer and the bottom surface of the second substrate.

16. The communication module package assembly of claim 10, wherein the first mounting legs of the metal cover have a length smaller than the length of the second mounting legs.

17. The communication module package assembly of claim 10, wherein the notches of the first carrier have a width greater than the width of the notches of the first substrate, the second carrier and the second substrate.

18. The communication module package assembly of claim 10, wherein the first substrate, the second substrate, the first carrier, the second carrier and the main board each have a plurality of contact pads for electrical connection.

19. The communication module package assembly of claim 10, wherein the communication module package comprises a chip electrically mounted on the bottom surface of the first substrate, received in the opening of the first carrier and encapsulated by the first thermal conductive layer.

20. The communication module package assembly of claim 19, wherein the communication module package further comprises a chip electrically mounted on the bottom surface of the second substrate, received in the opening of the second carrier and encapsulated by the second thermal conductive layer.
